(19) United States
(12) Patent Application Publication
(10) Pub. No.: US 2020/0382054 A1
(43) Pub. Date: Dec. 3, 2020

(54) SHINGLED SOLAR CELL WITH LOW FINGER PITCH

(71) Applicant: SOLARIA CORPORATION, Fremont, CA (US)

(72) Inventors: Denis DE CEUSTER, Fremont, CA (US); Kevin GIBSON, Fremont, CA (US)

(21) Appl. No.: 16/892,195

(22) Filed: Jun. 3, 2020

Related U.S. Application Data
(60) Provisional application No. 62/856,636, filed on Jun. 3, 2019.

(51) Int. Cl. H02S 40/34; H02S 30/00; H01L 31/05

(52) U.S. Cl. CPC H02S 40/34; H01L 31/05; H02S 30/00

(57) ABSTRACT

A shingled solar cell of High Density Module (HDM) design, exhibits reduced finger pitch (and hence increased finger count) relative to a corresponding non-HDM solar cell. A shingled HDM solar cell bearing a sole front side bus bar, may be fabricated by singulation from a larger non-HDM workpiece bearing a plurality of front side bus bars. Embodiments recognize that according to such a singulation-based HDM fabrication process, the resulting effective finger length (L_{EFF}) of the shingled HDM design will be longer than that for the non-HDM design. In order to compensate for increased resistance attributable to this longer HDM L_{EFF}, embodiments decrease the pitch between conductive fingers, thereby increasing the number of fingers actually occupying a given area of photovoltaic material. For purposes of collection efficiency, the reduction in finger pitch afforded by embodiments outweighs any shading penalty incurred by the larger finger count.

### CROSS-REFERENCE TO RELATED APPLICATION

The instant nonprovisional patent application claims priority to U.S. Provisional Patent Application No. 62/856,636 filed Jun. 3, 2019 and incorporated by reference in its entirety herein for all purposes.

### BACKGROUND

Photovoltaic devices are becoming an increasingly important element of global energy production. As technologies for creating photovoltaic materials are improved and economies of scale manifest, the price of photovoltaic material has been dropping at an exponential rate, making photovoltaic installations increasingly cost-competitive with other energy production technologies.

### SUMMARY

A shingled solar cell of High Density Module (HDM) design, exhibits reduced finger pitch (and hence increased finger count) relative to a corresponding non-HDM solar cell. A shingled HDM solar cell bearing a sole front side bus bar, may be fabricated by singulation from a larger non-HDM workpiece bearing a plurality of front side bus bars. Embodiments recognize that according to such a singulation-based HDM fabrication process, the resulting effective finger length (L_{EFF}) of the shingled HDM design will be longer than that for the non-HDM design. In order to compensate for increased resistance attributable to this longer HDM L_{EFF}, embodiments decrease the pitch between conductive fingers, thereby increasing the number of fingers actually occupying a given area of photovoltaic material. For purposes of collection efficiency, the reduction in finger pitch afforded by embodiments outweighs any shading penalty incurred by the larger finger count.

### BRIEF DESCRIPTION OF THE DRAWINGS

FIG. 1 shows a simplified perspective view of one singulated solar cell of a high density solar module (HDM).

FIG. 2 is an exploded view showing the position of the one singulated solar cell within a larger shingled assembly.

FIGS. 3A, 3B and 3C illustrate respective front, side and back surfaces of a photovoltaic string.

FIG. 4 illustrates overlapped photovoltaic strips in a string.

FIG. 5 is a simplified illustration of a photovoltaic module with four zones.

FIG. 6 illustrates an assembled photovoltaic module;

FIG. 7 plots power losses versus finger pitch for a shingled strip according to an embodiment.

FIG. 8 shows a simplified perspective view of the front side of a non-shingled solar cell comprising five bus bars.

FIG. 8A shows an enlarged cross-section of the non-HDM solar cell of FIG. 8.

FIG. 9 plots power losses versus finger pitch for the solar cell of FIG. 8.

FIG. 10 is a simplified diagram summarizing a process flow according to an embodiment.

FIG. 11 is an exploded view of a photovoltaic module.

FIG. 12 is a back view of a photovoltaic module without the backsheet.

FIG. 13 illustrates a conductive ribbon folded over an end of a string.

FIG. 14 illustrates a conductive ribbon configuration.

### DETAILED DESCRIPTION

A detailed description of embodiments is provided below along with accompanying figures. The scope of this disclosure is limited only by the claims and encompasses numerous alternatives, modifications and equivalents. Although steps of various processes are presented in a particular order, embodiments are not necessarily limited to being performed in the listed order. In some embodiments, certain operations may be performed simultaneously, in an order other than the described order, or not performed at all.

Numerous specific details are set forth in the following description. These details are provided in order to promote a thorough understanding the scope of this disclosure by way of specific examples, and embodiments may be practiced according to the claims without some or all of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

It is convenient to recognize that a photovoltaic module has a side that faces the sun when the module is in use, and an opposite side that faces away from the sun. Although, the module can exist in any orientation, it is convenient to refer to an orientation where “upper,” “top,” “front” and “aperture side” refer to the sun-facing side and “lower,” “bottom” and “back” refer to the opposite side. Thus, an element that is said to overlie another element will be closer to the “upper” side than the element it overlies.

Solar cells, also called photovoltaic (PV) cells, convert the sun's energy into electricity using semiconductors typically made of silicon. The cells are electrically connected to each other and assembled into a solar module. Multiple modules can be wired together to form an array. The larger and more efficient the module or array, the more electricity it can produce. Innovation is critical to optimizing solar module energy and reducing costs.

Embodiments of the present disclosure include high density strings of interconnected PV cells which are packed more efficiently onto the solar module to reduce inactive space between cells. Embodiments use advanced semiconductor manufacturing processes and equipment in which solar cells are scribed (cut) and singulated (separated) into highly-uniform strips, re-assembled into strings of cells, packaged and tested.

Square-type cells are typically assembled in a solar panel by connecting them in series with metal ribbons soldered along the bus bars, connecting the front bus bar to the corresponding backside bus bar of the next solar cell. When in operation, current is generated within the solar cell and collected by the electrodes, and flows from one solar cell to the next through the soldered metal ribbons.

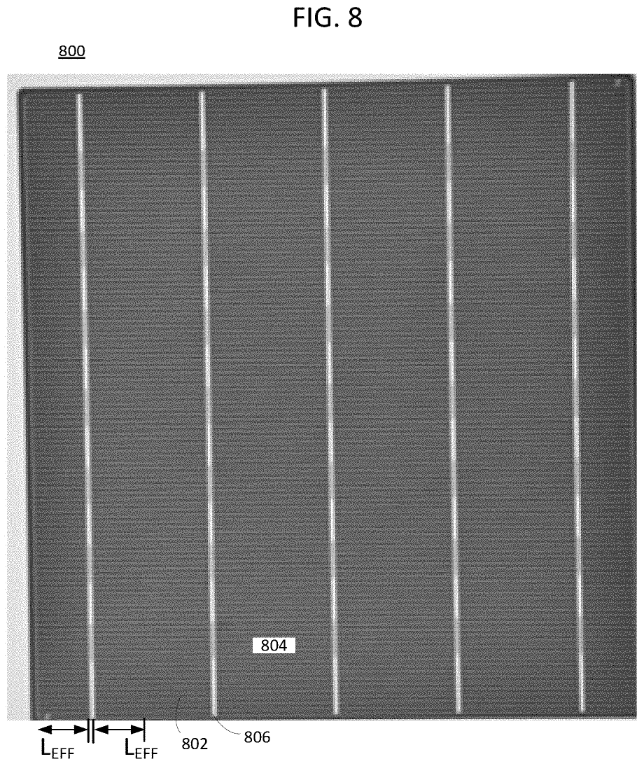

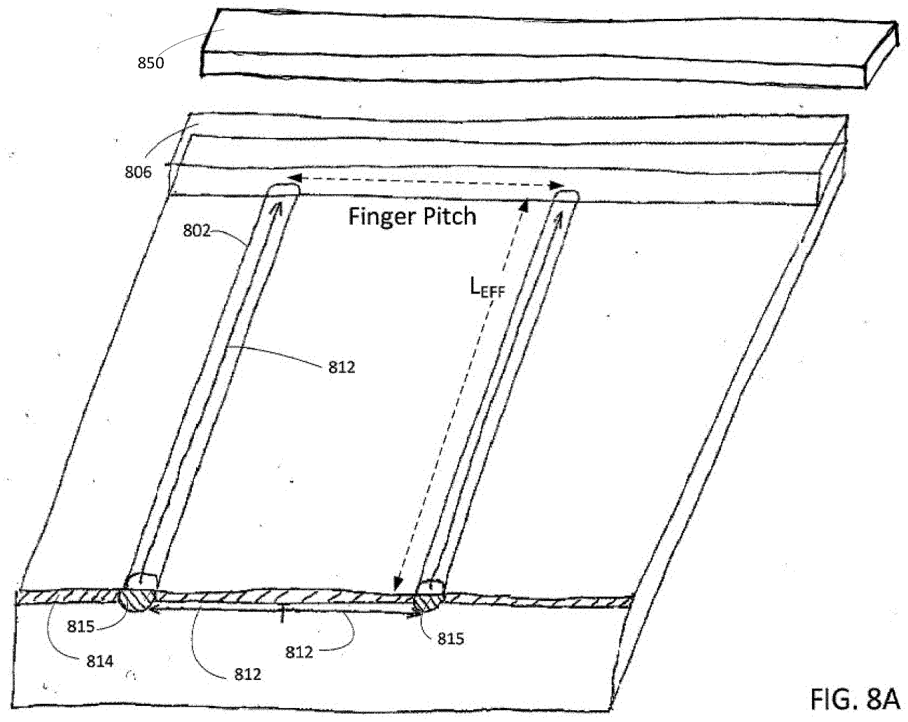

FIG. 8 shows a simplified view of a solar cell 800 having a square shape, with metal fingers 802 on the front surface 804, that are perpendicular and connected to a number (here five) of bus bars 806. As an example, in a solar cell having square dimensions of 156.75 mm, over one hundred fingers could be present.

The front electrode of the solar cell comprises this front metal structure. The backside electrode of the cell can be comprised of metal fingers and bus bars on the backside surface (or possibly with a metal covering all or most of the back surface).

In the most common configuration of a P-type solar cell with a front junction and a selective emitter, the front electrode collects electron current in the emitter diffusion, which is at the front surface and electrically connected to the front electrode. This is depicted in the simplified enlarged cross-section of FIG. 8A.

Specifically, the electrons 812 flow through the emitter diffusion 814 to the selective emitter 815 underlying the nearest finger 802, then through the fingers to the nearest bus bar 806 and finally through the ribbon 850 to the next solar cell.

Resistive losses occur through each step of this process—e.g., in the emitter, the fingers and the ribbons. In addition, fingers and ribbons shade the solar cells and reduce the generated current.

A properly designed front electrode will optimize the pitch of the fingers and the bus bars. Such pitch optimization considers factors such as minimization of the sum of the resistive and shading losses.

It is further noted that because the front electrode typically comprises (expensive) silver, cost is also considered. For this reason, the chosen finger pitch can be larger than the optimum number.

Advances in front electrode technology have allowed the formation of narrower frontside fingers. For example, circa 2010, typical finger width was about 100 μm, but narrower widths are possible.

The reduced finger width desirably reduces optical shading. However, it also undesirably increases the linear resistivity of the fingers, enhancing power losses and reducing efficiency.

In order to reduce resistive and shading losses associated with ribbons, High Density Module (HDM) designs utilizing shingled solar cells are proposed. The shape of a shingled solar cell is rectangular, i.e., having a long axis and a short axis.

In particular, the shingled solar cell is fabricated by separating a square solar cell in a number of rectangular strips. This separation may be accomplished utilizing techniques that include but are not limited to sawing and laser scribing.

The number of the rectangular strips may be 5 or 6 in number, where the original square solar cell has dimensions of 156.75 mm. However no particular number of strips or size of the original square solar cell, is required.

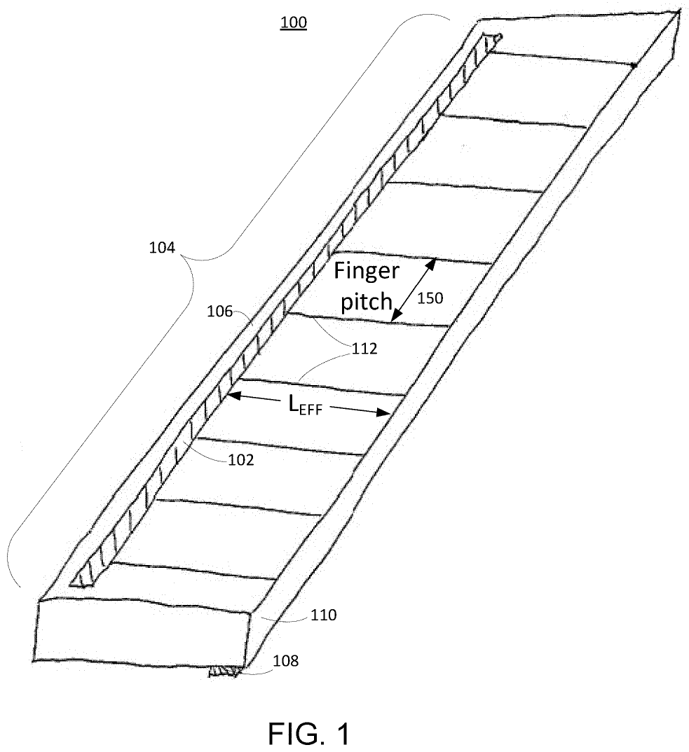

FIG. 1 shows a simplified perspective view of an individual singulated solar cell 100 of a HDM, in the form of a rectangular strip. The electrode design for a single cell includes a front bus bar 102 proximate to one of the long sides 104 of the rectangular strip 106, and a backside bus bar 108 close to the opposite side 110 of the rectangular strip.

Frontside fingers 112 run perpendicular to the bus bar 102. For simplification of illustration, a smaller number of fingers are shown in FIG. 1 than would actually be expected to be present (e.g., 100 or more). The distance between the parallel fingers (e.g., from a center of one finger to the center of the adjacent finger), is reference here as the finger pitch 150.

As an example only, the actual number of fingers may exceed one hundred for a HDM shingled cell having a long axis of 156.75 mm. Actual finger counts for particular embodiments are determined by the finger pitch.

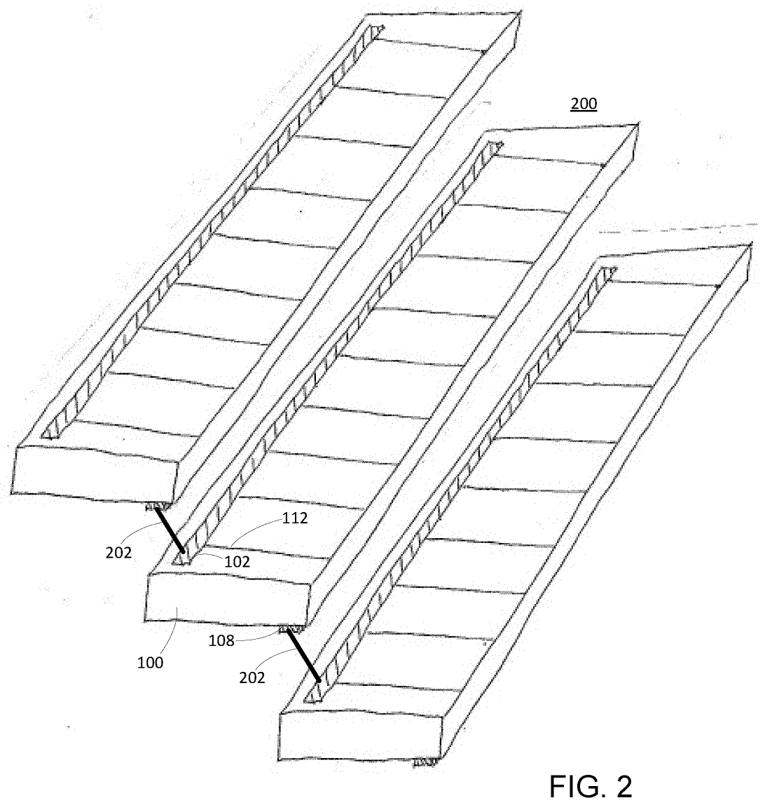

FIG. 2 is an exploded view showing the position of a single strip comprising the solar cell, in a shingled HDM assembly 200. In particular the singulated strips are connected in series as a string by overlapping the back bus bar of a strip over the front bus bar of the next strip. Electrical connection 202 between two shingled strips may be established utilizing soldering or electrically conductive adhesives.

With a shingled cell, no ribbon is necessary to carry the current from one strip to the next. Hence the electrical resistive losses associated with the ribbons are desirably reduced.

Moreover, the front bus bars of the singulated strip are entirely overlapped by the next strip. So, the ribbon shading losses are also eliminated. For at least these reasons such shingled technology may result in solar modules exhibiting increased efficiency.

Resistive losses associated with the solar cell fingers are now discussed. In particular, the photocurrent is generated essentially uniformly across the entire non-shaded surface of the solar cell.

The generated carriers take the path of least resistance toward the closest finger. Then, the carriers move through the fingers toward the closest bus bar. The current linearly accumulate in the finger in a manner proportional to the area of current collection.

In a non-HDM solar cell (such as is shown in FIG. 8), the effective finger length (L_{EFF})—the path with the maximum length of metal finger on which this current accumulates—is half the distance between two bus bars, or at the edges of the cell (outside the bus bars), the distance from the end of the fingers to the closest bus bar.

It is this L_{EFF} which determines the magnitude of resistance losses in the fingers. This L_{EFF} is labeled in FIG. 8.

At the edges of the non-HDM cell, L_{EFF} is the distance from the end of the fingers to the closest bus bar. This is also labeled L_{EFF} in FIG. 8A.

In contrast, for the shingled solar cell of a HDM design, the L_{EFF} which determines resistance losses, is different. As shown in FIG. 1, for the HDM case the L_{EFF} is the distance between the end of the finger and the bus bar. This L_{EFF} is labeled in FIG. 1.

Embodiments recognize that the finger length of the shingled solar cell of the HDM design of FIG. 1, may be longer in contrast with the finger length for the non-shingled solar cell of a non-HDM design. That longer L_{EFF} in turn affects the resistance, and hence the optimum number of fingers for the solar cell.

A shingled solar cell of High Density Module (HDM) design, exhibits reduced finger pitch (and hence increased finger count) relative to a corresponding non-HDM solar cell. A shingled HDM solar cell bearing a sole front side bus bar, may be fabricated by singulation from a larger non-HDM workpiece bearing a plurality of front side bus bars. Embodiments recognize that according to such a singulation-based HDM fabrication process, the resulting effective finger length (L_{EFF}) of the shingled HDM design will be longer than that for the non-HDM design. In order to compensate for increased resistance attributable to this longer HDM L_{EFF}, embodiments decrease the pitch between conductive fingers, thereby increasing the number of fingers actually occupying a given area of photovoltaic material. For purposes of collection efficiency, the reduction in finger pitch afforded by embodiments outweighs any shading penalty incurred by the larger finger count.

This difference in L_{EFF} may be further understood in connection with a specific example. In particular, a 5-bus bar non-HDM solar cell may have a bus bar width of 0.7 mm and an edge-to-edge distance of 156.75 mm. Here, non-HDM L_{EFF} distance is 15.325 mm.

By contrast a shingled HDM cell may be fabricated by singulating a 156.75 mm square non-HDM workpiece into only 5 strips, each having a bus bar of 0.7 mm width. For such a HDM solar cell, the L_{EFF} distance is doubled, to 30.65 mm.

As discussed in detail below in connection with Equation (1), the L_{EFF} distance is a factor for determining the resistive losses associated with the fingers.

Apart from the L_{EFF} distance, other such factors which may be considered in determining resistive losses, can include but are not limited to:
finger width;
finger shape and aspect ratio
finger thickness (height);
finger structure: e.g., comprising a single layer or as stack of multiple layers;
finger composition: e.g., resistivity of conductive material(s), including material stacks and/or alloys;
material density, porosity, or crystallinity;
purity of materials;
presence of additives;
process used to form the metal electrode, in particular thermal treatment

According to an embodiment, fingers may be fabricated with a width of 40 μm or less. Possible finger widths according to certain embodiments can be about 50 μm, about 35 μm 30 μm, about 25 μm, about 20 μm, about 15 μm, about 10 μm, or about 5 μm.

A variety of possible different materials may be used for the fingers. Representative resistances for metal width of 40 um are offered in the following table, with examples of average height as indicated.

| FINGER MATERIAL | LINEAR RESISTANCE |
|---|---|
| (average height) | (Ohm/cm) |
| Ag printed from silver paste (15 μm) | 0.68 |
| Ti/Pd/Ag (0.1 μm/0.1 μm/10 μm) | 0.40 |
| Chrome/Ni/Ag (0.1 μm/0.1 μm/10 μm) | 0.40 |
| Cu (12 μm) | 0.35 |
| Al (15 μm) | 0.44 |
| Au (10 μm) | 0.55 |

For a given:
current density (Jₘₚ),
finger—linear resistance (R_{LIN}), and
finger pitch (pitch) value,
   power loss density associated with the resistive losses through the fingers may be expressed as Equation (1) below:

R_{LOSS,FINGERS}=R_{LIN}/3*pitch*L_{EFF}²*Jₘₚ² (1)

This expression indicates that the quantity R_{LOSS,FINGERS}, is proportional to the square of the length of the L_{EFF} distance. So, everything else being equal, this resistive loss R_{LOSS,FINGERS}, will be quadrupled between a non-HDM cell having five (5) bus bars, and a corresponding HDM shingled cell of ⅕ the width of the non-HDM solar cell. Finger resistance can thus amount to a significant resistive loss.

Embodiments recognize the longer effective finger length for HDM solar cells. Since they are shingled, HDM cells exhibit this longer effective finger length, and the varieties of solar cell architectures calculated to reduce the sum of resistive and shading losses, differ from those of a non-HDM cell.

In particular, specific embodiments reduce resistive losses attributable to finger resistance in singled HDM solar cell designs, by reducing the finger pitch. This reduction in finger pitch results in an increased finger count for the same area of PV active material.

Reducing the finger pitch also reduces the resistive losses associated with the current path through the emitter. Similar to the resistive losses associated with the fingers, such losses are proportional to the square of the longest distance the carriers must travel to reach the nearest finger, which is half the distance between two fingers, and reducing the finger pitch reduces this distance.

It is noted that the shading loss associated with the finger coverage, is lower than the physical area of finger coverage. This effect may be described as having fingers of optical width smaller than the fingers of physical width

This effect arises from the fact that some of the light reflected on the finger surface can re-enter the cell area. This may be due to light being reflected at a shallow angle from the finger sidewalls. This may also be due to light being internally reflected by the glass/air surface back onto the cell surface.

Ultimately, a desirable finger count may result when the sum of: the shading losses, the finger resistive losses, and the emitter resistive losses, is minimized.

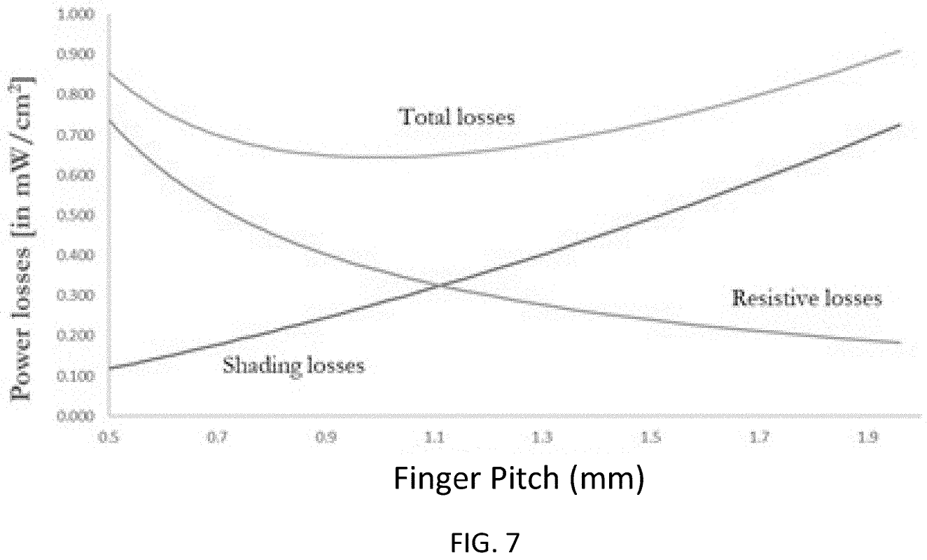

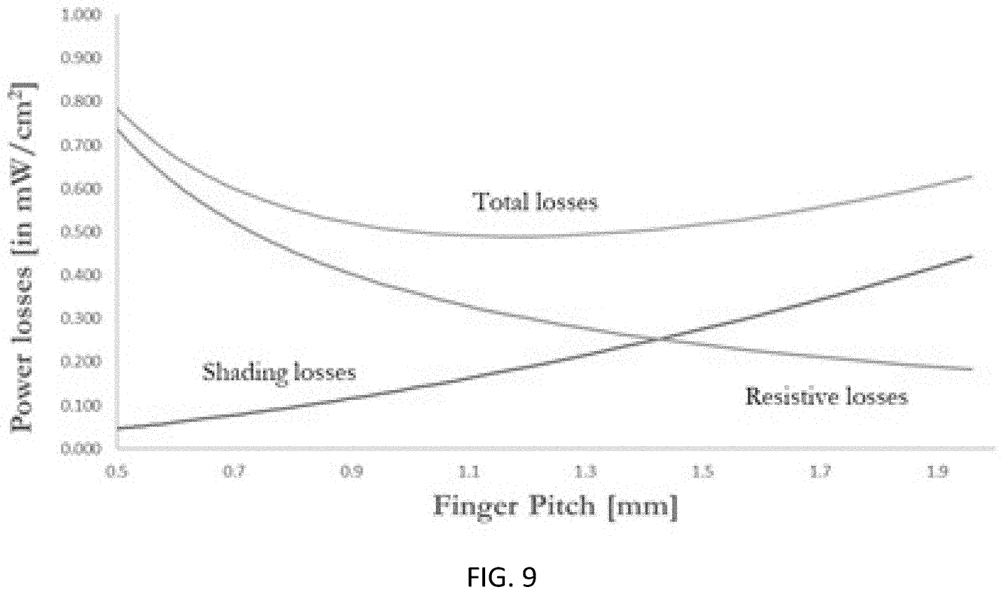

FIG. 9 plots the density of shading loss, resistive losses, and their sum, for a non-HDM five bus bar 156.75 mm cell. FIG. 7 plots the density of shading loss, resistive losses, and their sum for a 156.75×31.35 mm shingled HDM comprising singulated strips.

FIGS. 7 and 9 are based upon the following parameters:
finger physical width: 40 μm
finger optical width: 40% of the physical width
finger linear resistance: 0.4 Ω/cm
current density: 37 mA/cm²
an emitter sheet resistance: 80 Ω/square

The effective finger length is 15.25 mm for the non-HDM five bus bar design of FIG. 9. The effective finger length is 30.50 mm for the HDM shingle design of FIG. 7.

Inspection of FIGS. 7 and 9 shows that lowering the finger pitch of the HDM single design, reduces total losses as compared to the five-bus bar non-HDM design. In particular, FIG. 9 suggests an optimum finger pitch of 1.20 mm for the non-HDM five-bus bar design. This is compared with an optimum finger pitch of 1.00 mm for the HDM shingle design cell.

Examples of finger pitches which may be utilized for shingled HDM solar cell designs in accordance with embodiments, can include but are not limited to: 0.7 mm, 0.75 mm, 0.8 mm, 0.85 mm, 0.9 mm, 0.95 mm, 1.00 mm, 1.05 mm, 1.10 mm, 1.15 mm, and 1.20. Particular examples of finger pitches can include but are not limited to 1.10 mm, 1.11 mm, 1.12 mm, 1.13 mm, 1.14 mm, 1.15 mm, 1.16 mm, 1.17 mm, 1.18 mm, and 1.19 mm.

Although FIG. 7 describes shingled HDM solar cell designs resulting from singulation of a non-HDM workpiece having a width of 156.75 mm, embodiments are not limited to this particular example. A non-HDM workpiece may have a width of 160 mm, 164 mm, or 158 mm, for example.

It is noted that the desirable results achieved by embodiments may be even more pronounced in the case of bifacial HDM cells. There, the back side of the cell is also fabricated with a similar electrode design (including fingers and bus bars), in order to capture light incident to the back side of the cell (e.g., reflected or ambient light).

It is noted that lower dimensions for finger widths are currently around 35 μm. A trend further reducing finger width would increase R_LIN, and hence increase R_LOSS, an effect that may become even more pronounced for shingled HDM cells. Accordingly, progress in reducing finger width may encourage the reduction of finger pitch even more drastically for shingled HDM cells than for non-HDM cells. That is, reduced finger widths may demand designs with even further reduced finger pitch and hence cells having more than 130 fingers.

It is further noted that particular embodiments may not feature a front side bus bar. According to some embodiments, conductive fingers may be present on the front surface, with a bus bar present on the back surface. Electrical connection with the front side fingers of the strip may be established (e.g., using ECA) through the back side bus bar of an adjacent singulated strip of the shingled assembly.

As described in detail above, a HDM approach may feature a shingled arrangement of individual strips into a string. Further discussion regarding the assembly of singulated strips into strings, and assembly of strings into a larger solar module, is now provided.

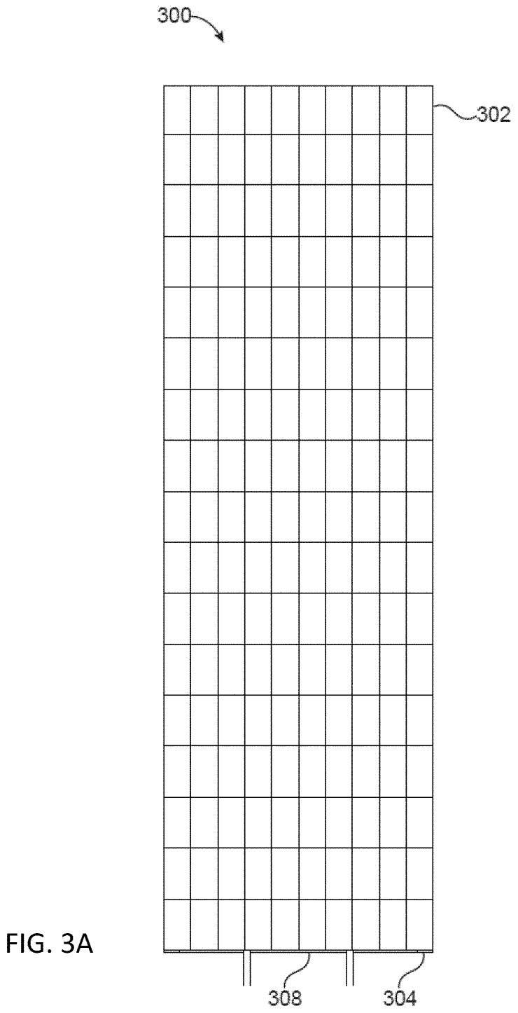

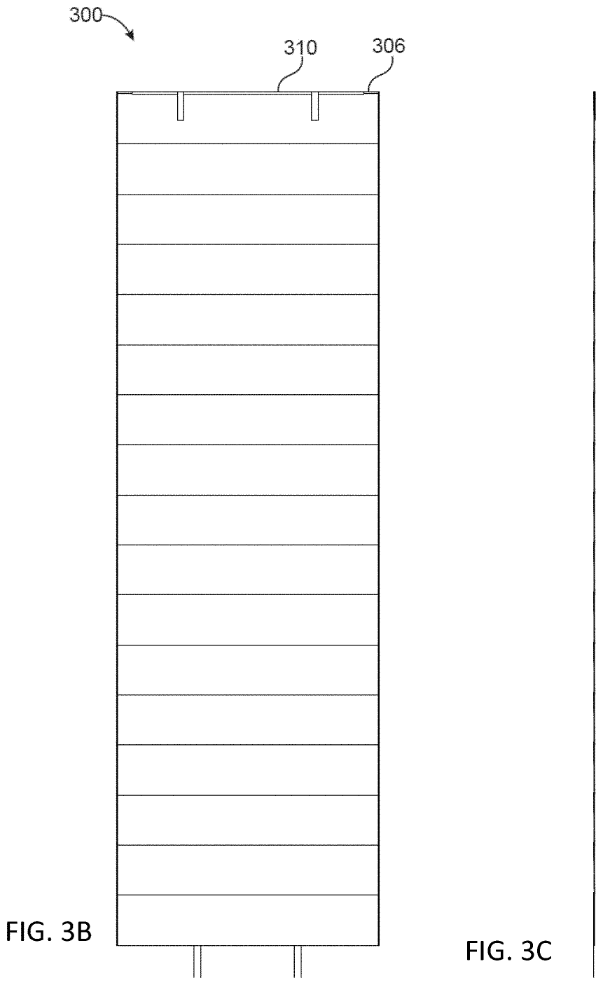

FIGS. 3A, 3B and 3C illustrate an embodiment of a string 300 that comprises a plurality of strips 302, each connected on a long edge to at least one other strip. FIG. 3A shows a front face of a string 300, FIG. 3B shows a back face of the string 300, and FIG. 3C shows a side view of the string 300.

In the embodiment of FIGS. 3A to 3C, the string 300 has seventeen (17) strips 302 coupled in series. However, the number of strips 302 in a string 300 can vary between different embodiments. For example, a string 300 may comprise two strips 302, ten strips 302, twenty strips 302, or fifty strips 302.

The number of strips 302 in a string 300 affects the electrical characteristics of the string. When strips 302 are connected in series to form a string 300, the current of an individual strip is the same as the current for the entire string, but the voltage of each strip is combined. In a simplified example, a string of 10 strips, in which each strip operates at 5 volts and 5 amps, would have an operating voltage of 50 volts and an operating current of 5 amps. Thus, arranging strips 302 into strings 300 facilitates adapting electrical characteristics of photovoltaic material.

As seen in FIG. 3C, strips 302 are arranged in an overlapped or tiled configuration within a string 300. In more detail, front bus bars 304 of strips 302 in the string 300 overlap with and are electrically and mechanically coupled to back bus bars 306 of adjacent strips. In embodiments, the strips 302 may be connected by a material such as a metallic solder or an electrically conductive adhesive (ECA).

An ECA has several advantages as a coupling material in a string 300. Polymeric components of ECA can provide higher elasticity than metal materials, which can help maintain a mechanical bond under various thermal states when the materials contract and expand. In other words, the ECA can relieve mechanical stress caused a coefficient of thermal expansion (CTE) mismatch between mated materials. ECA can be formulated to be soluble to various solvents, which facilitates various manufacturing processes. In addition, an ECA bond is typically more elastic than, for example, a solder bond, so an ECA bond is less prone to cracking during assembly.

In an embodiment in which strips are connected by ECA, the ECA may be a cured adhesive polymer formulation that is highly loaded with conductive metal particles. In some embodiments, the conductive metal is silver. The ECA may be a thermosetting acrylate adhesive. The adhesive may have may be modified with one or more hardening components such as epoxy, phenol-formaldehyde, urea-formaldehyde, etc., that provide hardness and bonding strength. In an example, the ECA is a low temperature cure one-part adhesive.

When strips 302 are connected in series in a string 300, bus bars at the far ends of the string are exposed. In other words, unlike strips 302 in the middle of a string 300, one bus bar of the outermost strips in a string is connected to an adjacent strip, but one bus is not connected to a strip. Instead, in embodiments of the present disclosure, bus bars of the outermost strips 302 are connected to conductive ribbons.

In embodiments of the present disclosure, a system utilizes a ⅕th strip width versus ⅓rd, ¼th or ⅙th of a cell strip width.

Here, width refers to the width of a strip after it has been cut from a cell. Current is the amount of current that a strip produces, which is directly proportional to the size of the strip. Fingers carry current across a strip, while shading is the area of the strip shadowed by the fingers. Cell utilization is the amount of area in a string in which strips do not overlap one another. The number of placements is how many strips are cut from a cell and placed in a string. Fill factor is the efficiency of the photovoltaic material present in a string compared to its maximum power producing potential.

In an example, modules are configured to have current and resistance characteristics that are similar to a conventional module (Voc, Vmp, Isc, Imp, Power). However, modules can be designed to have different characteristics for different applications. For example, modules created according to embodiments of this disclosure can be configured to have lower voltage and higher current for the solar tracking applications, and to have higher voltage and lower current for residential modules that interface with module power electronics.

In an example, one embodiment uses a 31.2 mm strip width, which optimizes module characteristics, as well as providing a current and voltage similar to standard modules. This allows embodiments to take advantage of standard inverters, electronics, and mechanical features.

FIG. 3A shows a front ribbon 308 over the exposed front bus bar 304 of the lowermost strip 302 in the string 300. As seen in FIG. 3B, a back conductive ribbon 310 covers the back bus bar 306 at of the uppermost strip 302 of the string 300. The back bus bar 306 is the back terminal of a strip 302, and front bus bar 304 is a front terminal. Each of the front and back ribbons 308 and 310 has two tabs protruding from the respective the ribbon. In a flat orientation, the tabs of the front ribbon 308 extend outward from the string 300, while the tabs of back ribbon 310 extend inwards from the edge strip to which the back ribbon 310 is attached towards the middle of the string. In an embodiment, the front surface of a strip 302 has a positive polarity and the back surface has a negative polarity. However, other embodiments are possible, where the exposed front aperture surfaces has negative polarity and the back surface has positive polarity.

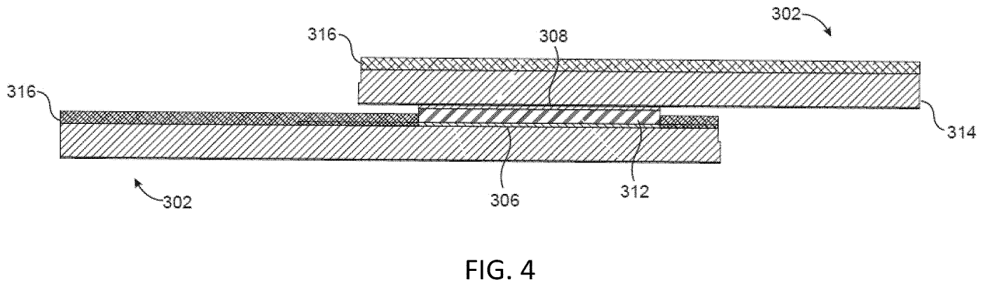

FIG. 4 shows a detail view of an overlapped joint in which two adjacent strips 302 are connected to one another in a string 300. The overlapped open ends of the strips 302 have a staggered profile, which results from a separation process in which PV cells are separated using two distinct operations, e.g. a scribe operation and a breaking operation. A cutting operation may result in a kerf in the inset portion of the edge, while a breaking operation does not cause a kerf, resulting in the slight protrusion visible in FIG. 4.

Each strip 302 in the string 300 has a thickness of PV material 314 and a thickness of a backing material 316. In many conventional PV cells, the backing material 316 is aluminum, but embodiments are not limited to that material. A back bus bar 306 is exposed by the backing material 316, and a layer of ECA 312 mechanically and electrically couples the back bus bar 306 to a front bus bar 308 on the overlapped strip 302.

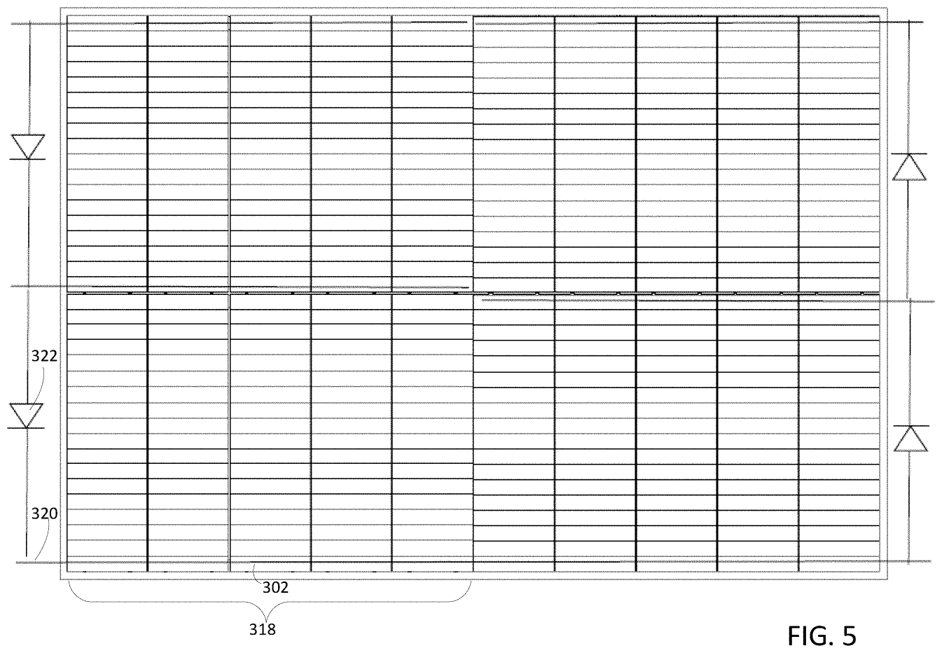

FIG. 5 is a simplified diagram of a photovoltaic apparatus that comprises a plurality of strings 300 that are arranged into a plurality of zones 318. In the specific embodiment shown by FIG. 5, each string 300 has 20 strips 302 connected in series with one another. Each string 300 is connected in parallel with five additional strings through electrical busses 320 disposed at opposing ends of the parallel connected strings, so that a total of six strings are connected in parallel. Each set of strings 300 connected in parallel is referred to herein as a “zone” 318.

The number of strings 300 in a zone 318 may vary between embodiments. For example, other embodiments may have from two to ten strings 300 in a zone 318. In addition, the number of zones 318 in a module can vary between embodiments.

The embodiment shown in FIG. 5 has four separate zones 318, and each zone is protected by a single diode 322 coupled in parallel to the five strings 300 in the respective zone. Conventional PV module arrangements are divided into multiple cells that are all connected in series with one another, and diodes are periodically disposed between sub-groups of the series connected cells. In such conventional arrangements, when a single cell is disabled, for example by being shaded, all other cells coupled to the same diode are also disabled. In other words, in conventional devices, when one cell is disabled, all cells that are coupled to the diode that protects the disabled cell are also disabled.

In contrast, the PV device shown in FIG. 5 has better performance. Each diode 322 protects a zone 318 in a much more efficient manner than conventional devices. Like conventional devices, when one or more strip 302 in a first string 300 is disabled, all of the strips in the first string are disabled, and current flows through the diode 322. However, unlike conventional devices, all other strings 300 that are present in the same zone 318 and do not have any disabled strips 302 continue to produce normal levels of energy. Accordingly, energy losses due to shading are much lower in embodiments of the present application than conventional devices.

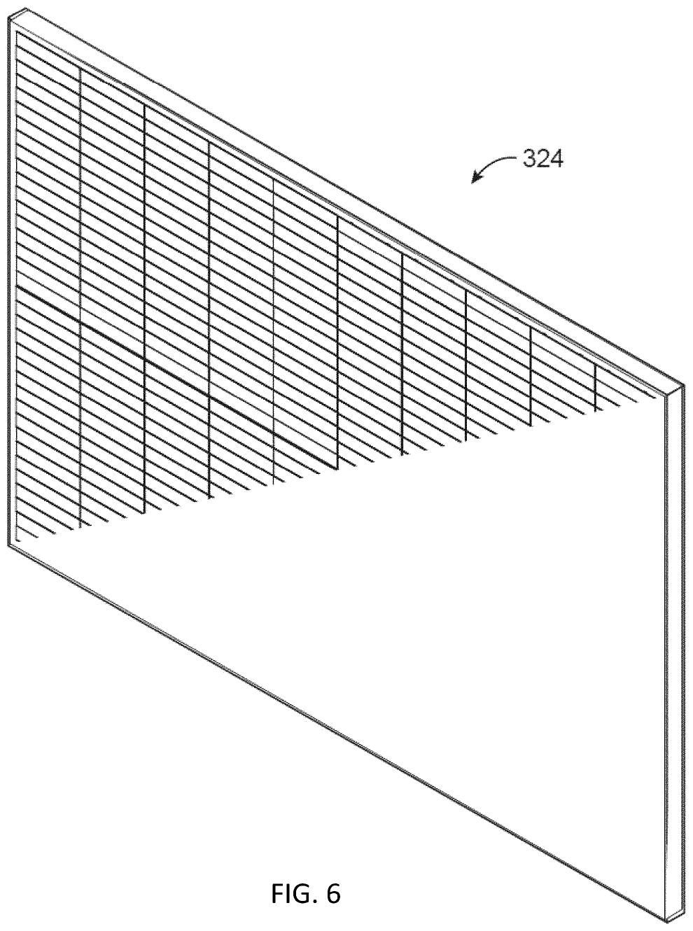

FIG. 6 shows an example of a PV module 324 that includes the photovoltaic components shown in FIG. 5. In more detail, the PV module 324 shown in FIG. 6 has 20 strings 300, and each string 300 has twenty (20) of strips 302 that are mechanically and electrically connected in series with one another.

Returning to FIGS. 3A and 3B, the front bus bar 304 of a string 300 is covered by a front ribbon 308, and the back bus bar 306 is covered by back ribbon 310. The ribbons are mechanically and electrically connected between the respective bus bars of the PV string 300 and electrical busses 320.

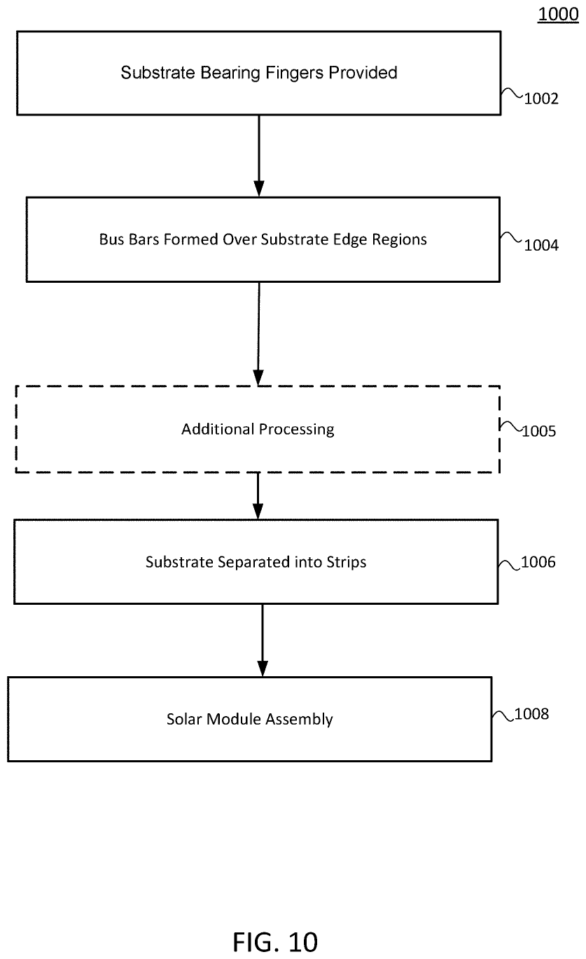

FIG. 10 is a simplified diagram illustrating a generalized process flow 1000 according to an embodiment. At 1002, a semiconductor substrate bearing a plurality of thin electrically conductive fingers oriented in parallel along a first axis, is provided. On each end, the thin conductive fingers stop short a distance from an edge of the substrate.

At 1004, a plurality of front bus bars are formed in parallel along a second axis to overlap the thin electrically conductive fingers. Of these, two edge front bus bars overlap and cover the respective distances at each end of the substrate. Other front bus bar(s) are located in the interior region of the substrate surface, away from the ends, overlapping the continuous thin conductive fingers in an interior region of the substrate.

At 1005, additional structures may be formed on the substrate. For example, back side bus bars may be formed on the back side of the substrate. In particular, those back side bus bars may be formed specifically aligned with the expected location of the lines along which the individual strips will be separated.

At 1006, the substrate is separated along separation lines into individual strips having respective front side bus bars. In particular, a first end strip includes a first front bus bar covering a distance at the first edge of the substrate. A second end strip includes a second front bus bar covering a distance at the second edge of the substrate opposite from the first edge. A third end strip includes a third bus bar present in an interior region of the substrate.

At 1008, the first, second, and third strips are assembled into a solar module.

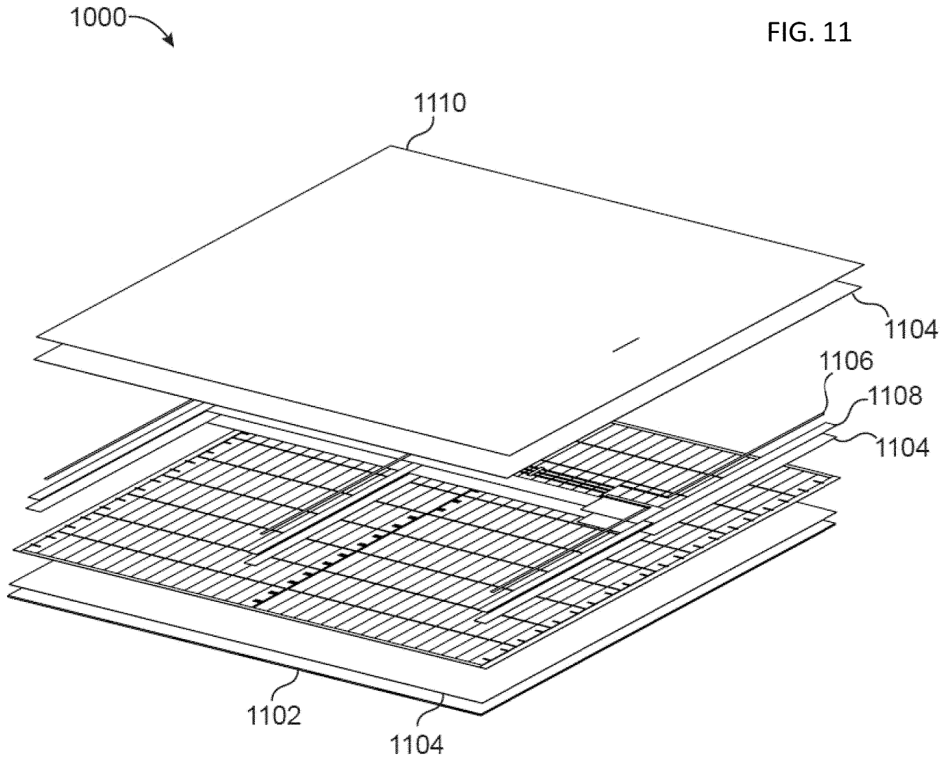

Assembly of a module from separated strips according to certain embodiments, is now discussed. FIG. 11 illustrates a back-facing view of components of an embodiment of a PV module 1100.

An outer surface of PV module 1100 is a glass panel 1102, and a translucent laminate material 1104 is disposed between the glass panel and the aperture side of PV elements. In an embodiment, the laminate material 1104 is a sheet of EVA film that encapsulates the PV elements when the PV module 1100 is assembled. When a PV module is assembled, heat, vacuum and pressure may be applied to components of the module shown in FIG. 11 so that the laminate material seals and bonds to adjacent components.

PV elements are disposed directly beneath the laminate 1104. In an embodiment of the present disclosure, the PV elements are a plurality of strings 300, each of which comprises a corresponding plurality of strips 302. Each of the strings 300 has a front ribbon 700 disposed on a first end of the string, and a back ribbon 800 disposed on an opposing second end of the string.

Bus wiring 1106 is disposed behind the plurality of strings 300. The bus wiring 1106 connects front and back terminals of the PV strings 300 to circuitry of the PV module. Although the present embodiment uses flat bus wiring 1106, other embodiments may use other wire shapes.

A plurality of insulation patches 1108 are disposed between the PV material and the flat bus wiring 1106 to prevent electrical shorts between conductive elements of the PV module 1100. A second translucent element 1004 is disposed behind the bus wiring 1106 and insulation patches 1108, followed by a backsheet 1110 which forms an outer backing surface of the PV module.

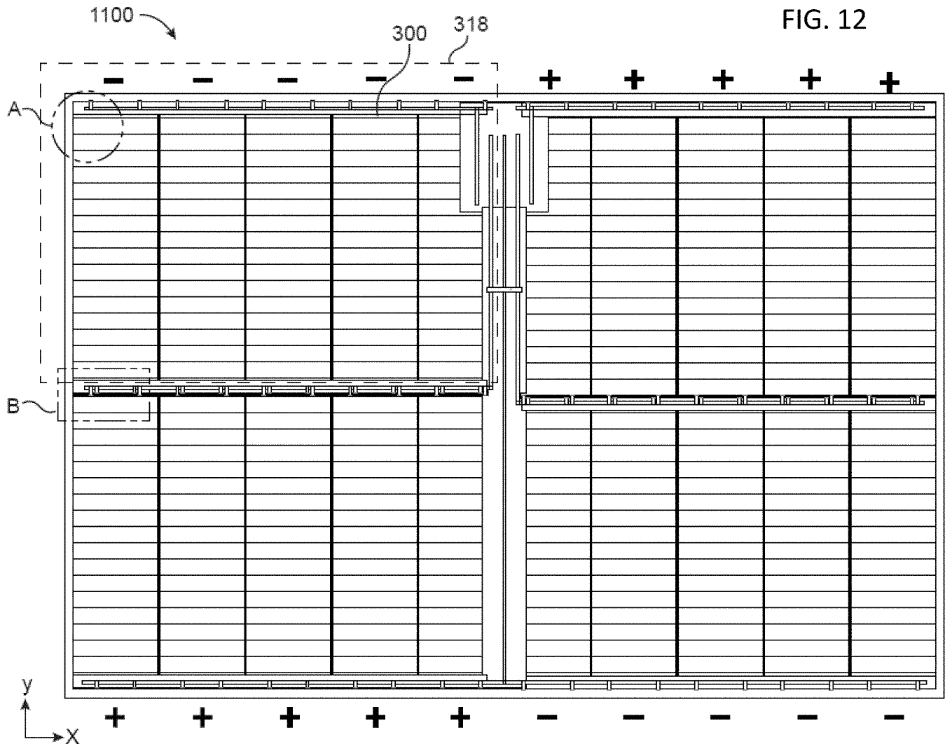

FIG. 12 illustrates a back view of a PV module 1100. As seen in the embodiment of FIG. 12, five PV strings 300 are arranged in parallel to one another to create four separate zones 318. Each of the PV strings 300 of each zone 318 have opposing terminal ends that are aligned with each other and commonly coupled to the same bus wire 1106. Zones are arranged so that a front terminal of one zone 318 is adjacent to a back terminal of an adjacent zone.

For example, the front terminal end of the zone in the lower left sector of FIG. 12 is directly adjacent to the back terminal end of the zone in the upper left sector, or the X direction as indicated in the figure. Similarly, the back and front terminal ends of each zone 318 are in an opposite orientation from the orientation of an adjacent zone in the Y direction. As a result, each terminal end of each zone 318 is adjacent to a terminal end of another zone with an opposite polarity.

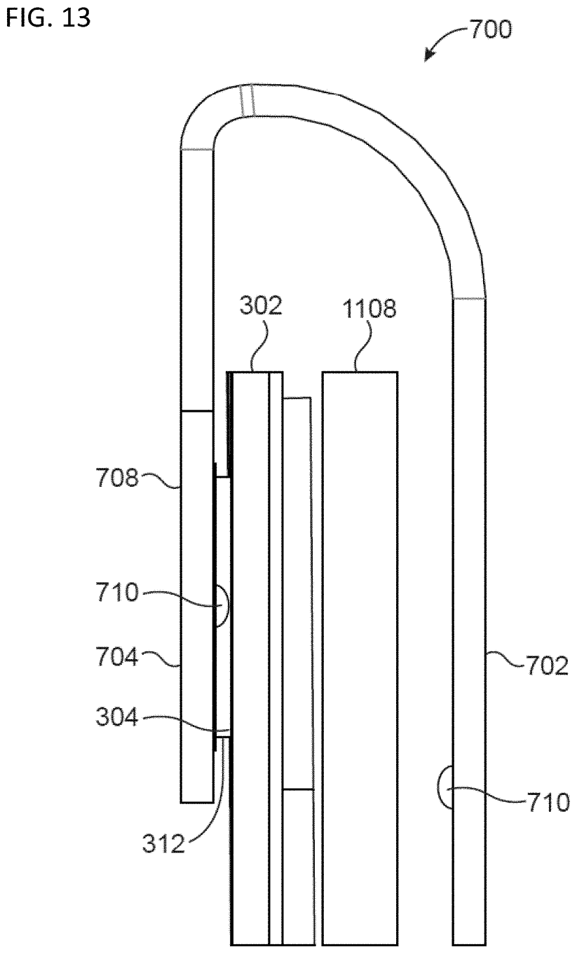

FIG. 13 is a detail view of section A of FIG. 12 and shows a front terminal end of a PV strip 302 of a PV string 300 according to an embodiment of the present disclosure. A bus interface portion 704 of front ribbon 700 is coupled to a front bus bar 304 through a layer of ECA 312. Tabs 702 of the front ribbon 700 extend past the edge of the PV strip 302 by a predetermined distance that may be 1.0 mm or less, or between 0.5 mm and 2.0 mm. The gap created by the predetermined distance may prevent damage to the PV material.

In an embodiment, a tool is used to form the bend the front ribbon 700 over the edge of the PV strip 302. The tool may ensure that the predetermined gap is provided while fixing the ribbon material in place so that the ECA bond is not compromised when the tabs are bent. The tabs may be bent 180 degrees from a flat orientation so that they extend in an opposite direction compared to a flat orientation of the ribbon 700.

An opaque coating material 708 is present on outward-facing portions of the front ribbon 700 that are visible when a PV module 1000 is assembled. The entire bus interface portion 704 of the front ribbon is coated with the opaque coating 708. In addition, portions of the tabs 702 are coated with coating 708 so that the coated portion of the tabs is contiguous with the coating over the bus interface 704. The portions of the tabs 702 that are coated are portions that that are folded over the edge of the PV strip 302. In an embodiment in which a coating material is present in those areas of the conductive ribbon 700, no reflective surfaces of the conductive ribbon are visible in an assembled PV module 1000.

An insulation patch 1108 is disposed between a backside surface of the PV strip 300 and an inner surface of front ribbon 700. The insulation patch 1108 may be secured to the backside surface of the PV strip 302 by an adhesive or laminate material such as EVA. In the embodiment shown in FIG. 12, conductive protrusions 710 that extend from a surface of the bus interface 704 are aligned with the front bus bar 304 of the PV strip 302, and provide a low resistance connection between the front ribbon 700 and the PV strip. In contrast, the conductive protrusions 710 on tabs 702 face inwards towards insulation patch 1008. Accordingly, in the embodiments shown in FIG. 12, the conductive protrusions 710 on the tabs 704 are not in a conductive path between the ribbon 700 and a bus of a PV strip 302.

One of the advantages that conductive ribbons provide over conventional solar modules is reducing current density. Embodiments of the bus interface parts 704 and 804 cover the entire surface of the font busses, and ECA is present in most or all of the space between the bus interface parts and the busses. Accordingly, the current density of such embodiments is much lower than the current density of conventional modules, in which the area of the conductive interface is limited to solder connections to which wires are connected.

Returning to FIG. 12, the tabs 702 of front ribbons 700 disposed on outer edges of the PV strings 300 on a top edge of the module are connected to a first flat bus wire 1106. Similarly, tabs 802 of back ribbons 800 along the top edge are coupled to a second bus wire 1106. In contrast, the tabs 702 and 802 of respective front and back ribbons 700 and 800 that are disposed along bottom edge of the module 1100 are commonly coupled to the same bus wire 1106. Similarly, front ribbons 700 and back ribbons 800 of adjacent edges of adjacent zones 318 are commonly coupled to the same bus wire 1106.

The connection between tabs of the front and back ribbons and the bus wiring 1006 may be a solder connection or an ECA connection. When an ECA connection is present, conductive protrusions disposed on the tabs may be aligned with the ECA material. In some embodiments, the conductive protrusions on tabs of a conductive ribbon may be present on an opposite face of the ribbon from the conductive protrusions on the bus interface part of the same ribbon. In other words, conductive protrusions on a ribbon's tabs may be on the opposite face from the conductive ribbons on the ribbon's bus interface.

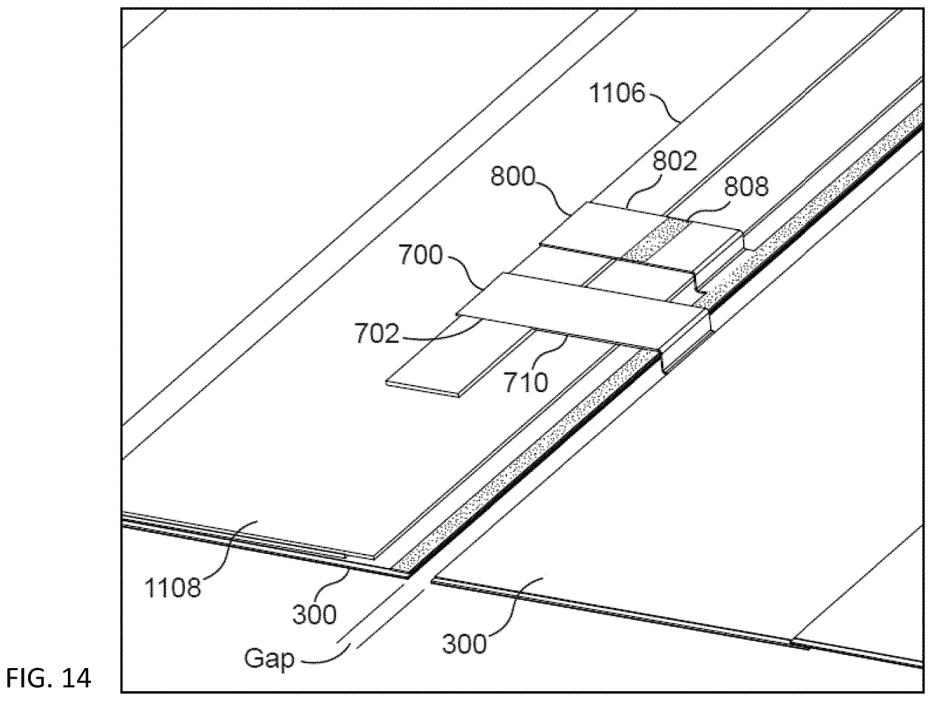

FIG. 14 is a detail view of section B of FIG. 12, and shows ribbon configurations for adjacent PV strings 300. A bus interface 804 of the back ribbon 800 is coupled to the back bus bar 306 of an edge strip 302 so that the coated surface of the back ribbon faces outwards from the back face of the PV material. In an embodiment, an insulation patch 1108 is coupled to the back surface of the PV material, and may be retained by an adhesive or laminate material such as EVA.

Tabs 802 of back ribbon 800 extend away from bus interface 804, fold over the insulation patch 1108, and are coupled to the bus wiring 1106. Tabs 702 of the front ribbon 700 fold over from the front of the strip to which they are attached to the back surface of the strip 302 to which the back ribbon 800 is attached.

Accordingly, the tabs 802 of the back ribbon 800 attached to a first string 300 are aligned in parallel with the tabs 702 of the front ribbon 700 of a second string 300 that is adjacent to the first strip. Therefore, in an embodiment in which opposing terminals of PV strings 300 are adjacent to one another, tabs of respective conductive ribbons are routed in the same direction and are commonly coupled to the same bus wire 1106.

Returning to FIG. 12, the efficient and unique arrangement of components in a PV module 1100 provides a number of technological advantages. Use of the same bus material 1106 to connect tabs of conductive ribbons from opposite poles of adjacent zones 318 achieves simultaneous series connections between separate zones and parallel connections between strings 300 within the same zone, as seen in FIG. 5, while minimizing the number of connections and the amount of materials in a panel. Therefore, a PV module 1100 according to an embodiment of the present application is highly efficient and reliable.

In addition, elements of the panel arrangement of the panel 1100 provide a PV panel that does not have reflective surfaces that are visible from the aperture side of the panel. Tiling of PV strips in each of the strings hides metallic bus bars that are visible in conventional panels. Although a PV strip 302 at each end of a PV string 300 has one bus region for which a metallic bus bar would be exposed, embodiments of the present application completely cover that bus bar with a conductive ribbon, and all surfaces of the conductive ribbon that are visible in an assembled PV module are covered with an opaque coating material. Meanwhile, the PV strings are arranged in the panel so that no gaps greater than a few millimeters are present between adjacent strips and strings, and what gaps are present are minimal in size. Components of the PV module may be attached to form a mechanical sub-structure that retains components in place during a lamination process to ensure that gaps and alignment are maintained to a high tolerance.

Apart from the coated surfaces of the conductive ribbons, no bus wiring is visible from an aperture side of a PV module 1100. The only reflective elements than can be perceived from the aperture side of a PV module 1100 according to an embodiment of the present disclosure are the fingers that run across the surface of PV material, and the fingers are too small to be noticeable from a distance of 10 feet or more, so that fingers are not perceived as reflective surfaces from most viewing positions of a typical PV installation.

In some embodiments, solar modules may use PV strips that do not have busses that comprise conductive material on the solar cells, or “busbarless” cells. For example, embodiment may use strips that are cut from cells such as the cells shown in design patent applications 29/646,603 and 29/646,604, each of which is incorporated by reference herein. In such embodiments, conductive ribbons may be coupled to areas that correspond to the areas in which conductive bus material is normally applied, which may be referred to as bus regions. The conductive interface between conductive ribbons and a bus region of a busbarless strip may be an ECA material that interfaces with the conductive fingers that are oriented orthogonal to the ribbon junctions. A busbarless cell has numerous advantages over a cell with printed busbars, including lower cost and a superior electrical connection between the fingers and adjacent cells that are overlapped and coupled with ECA.

While the above is a full description of the specific embodiments, various modifications, alternative constructions and equivalents may be used. Although the above has been described using a selected sequence of steps, any combination of any elements of steps described as well as others may be used. Additionally, certain steps may be combined and/or eliminated depending upon the embodiment.

Of course there can be other variations, modifications, and alternatives. Therefore, the above description and illustrations should not be taken as limiting the scope of the present invention which is defined by the appended claims.

What is claimed is:

1. An apparatus comprising:
a first singulated rectangular silicon photovoltaic material having a front surface, a long side, and a short side;
a first sole bus bar on the front surface proximate to an edge of the first singulated rectangular silicon photovoltaic material at the long side; and
a plurality of parallel conductive fingers overlying the front surface and intersecting the bus bar, the plurality of parallel conductive fingers separated by a finger pitch of less than 1.2 mm.

2. An apparatus as in claim 1 wherein the plurality of conductive fingers comprise silver.

3. An apparatus as in claim 1 wherein the finger pitch is greater than 0.7 mm and less than 1.2 mm.

4. An apparatus as in claim 1 further comprising:
a second singulated rectangular silicon photovoltaic material having a back surface overlapping the first bus bar along the long side to form a shingled strip, the second singulated rectangular silicon photovoltaic material comprising,
a front surface,
a second sole bus bar on the front surface proximate to an edge of the second singulated rectangular silicon photovoltaic material at a long side, and
a second plurality of parallel conductive fingers overlying the front surface and intersecting the second bus bar, the second plurality of parallel conductive fingers separated by the finger pitch.

5. An apparatus as in claim 4 wherein the first singulated rectangular silicon photovoltaic material and the second singulated rectangular silicon photovoltaic material are singulated from a workpiece comprising the first sole bus bar and the second sole bus bar.

6. An apparatus as in claim 4 wherein the first singulated rectangular silicon photovoltaic material and the second singulated rectangular silicon photovoltaic material are singulated from a workpiece having a width of between about 156-166 mm.

7. An apparatus as in claim 6 wherein the finger pitch is about 1.00 mm.

8. An apparatus as in claim 4 wherein a width of each of the first plurality of parallel conductive fingers, and of each of the second plurality of parallel conductive fingers, is about 0.35 μm.

9. An apparatus as in claim 4 wherein each of the first plurality of parallel conductive fingers has an effective length of about 30.50 mm.

10. An apparatus as in claim 1 wherein the first singulated rectangular silicon photovoltaic material is bifacial.

11. A method comprising:
providing an integrated workpiece comprising photovoltaic silicon material bearing,
a plurality of parallel conductive fingers separated by a finger pitch of between about 0.7 and 1.19 mm, and
a plurality of parallel bus bars intersecting the plurality of parallel conductive fingers; and
singulating the integrated workpiece into a first high density module (HDM) solar cell bearing a first bus bar of the plurality of bus bars and a first portion of the plurality of conductive fingers having an effective length.

12. A method as in claim 11 further comprising:
singulating the integrated workpiece into a second high density module (HDM) solar cell bearing a second bus bar of the plurality of bus bars and a second portion of the plurality of conductive fingers having the effective length; and
overlapping the second HDM solar cell with the first bus bar to establish a first serial electrical connection.

13. A method as in claim 12 wherein the first serial electrical connection is established by adhesive.

14. A method as in claim 12 wherein the first serial electrical connection is established by solder.

15. A method as in claim 12 further comprising:
placing the first serial electrical connection in parallel electrical communication with a plurality of additional HDM solar cells arranged in a second serial electrical connection and each having a plurality of parallel conductive fingers separated by the finger pitch and having the effective length.

16. A method as in claim 12 wherein:
the integrated workpiece has a dimension of 156.75 mm.
the effective length is about 30.50 mm.

17. A method as in claim 12 wherein the first HDM solar cell and the second HDM solar cell are bifacial.

18. A method of designing a high density module (HDM) solar cell, the method comprising:
decreasing a first finger pitch and increasing a first finger count of a first plurality of parallel conductive fingers having a first effective length on a first singulated rectangular silicon photovoltaic material, relative to,
a second finger pitch and to a second finger count respectively, of a second plurality of conductive fingers having a second effective length shorter than the first effective length on a corresponding integrated workpiece bearing a plurality of bus bars,
wherein a front surface of the first singulated rectangular silicon photovoltaic material includes a sole bus bar intersecting with the first plurality of parallel conductive fingers having the first finger count and separated by the first finger pitch, and
wherein the first finger pitch is between about 0.7 mm and 1.9 mm.

19. A method as in claim 18 wherein the corresponding integrated workpiece has a dimension of 156.75 mm.

20. A method as in claim 18 wherein the HDM solar cell is bifacial.
